(19) United States
(12) Patent Application Publication
(10) Pub. No.: US 2014/0177172 A1
(43) Pub. Date: Jun. 26, 2014

(54) FAN CONTROL SYSTEM AND METHOD

(71) Applicant: HON HAI PRECISION INDUSTRY CO., LTD., New Taipei (TW)

(72) Inventors: Po-Wei WANG, New Taipei (TW); Li-Wen CHANG, New Taipei (TW); Chih-Chung SHIH, New Taipei (TW)

(73) Assignee: HON HAI PRECISION INDUSTRY CO., LTD., New Taipei (TW)

(21) Appl. No.: 13/965,209

(22) Filed: Aug. 13, 2013

(30) Foreign Application Priority Data
Dec. 25, 2012 (TW) 101149659

(51) Int. Cl. H05K 7/20

(52) U.S. Cl. CPC H05K 7/20209
USPC 361/695

(57) ABSTRACT

A processor in a multi-node system includes a detecting module which obtains temperatures of all nodes periodically. A comparing module compares all obtained temperatures to obtain a greatest temperature. A determining module determines a fan speed value corresponding to the greatest temperature according to a predetermined table which records relationships of temperatures and fan speed values. A control module controls all fans to work at the fan speed value corresponding to the greatest temperature.

### BACKGROUND

1. Technical Field

The present disclosure relates to fan control systems and methods, more particularly, to a fan control system and a method used in multi-node systems.

2. Description of Related Art

Mainboards can control internal fans to work when an internal temperature goes up. However, this is not available for fans working in multi-node systems.

Therefore, it is desirable to provide a fan control system and method used in multi-node systems, which can overcome the above-mentioned problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments.

FIG. 1 is a schematic view of a multi-node system in accordance with an embodiment of the present disclosure.

FIG. 2 is a schematic view of a fan control system used in the multi-node system in FIG. 1.

FIG. 3 is a flowchart of a method of controlling fans to work in the multi-node system of FIG. 1.

### DETAILED DESCRIPTION

Embodiments of the present disclosure will be described with reference to the drawings.

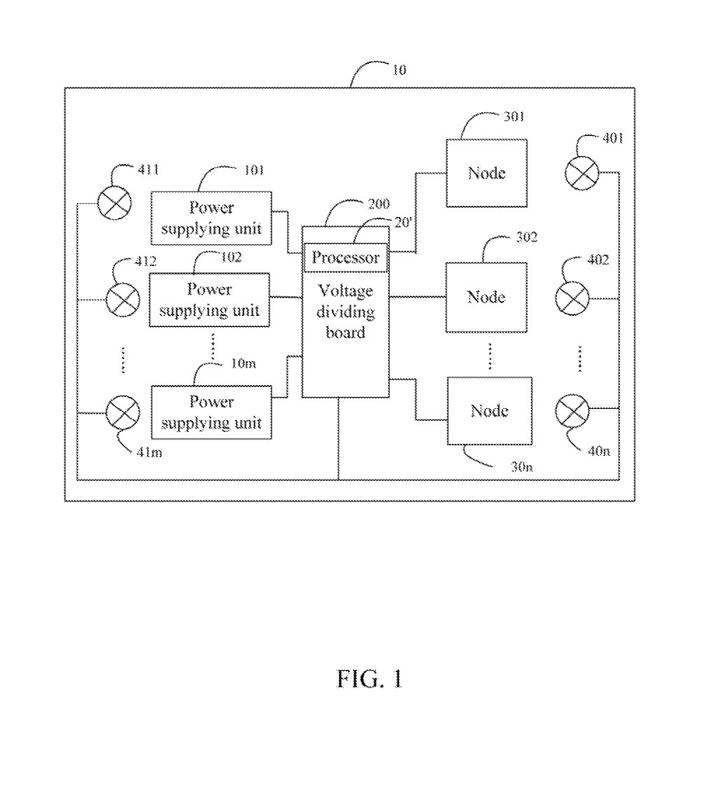

FIG. 1 is a schematic view of a multi-node system in accordance with an embodiment of the present disclosure. The multi-node system 10 includes several power supplying units 101, 102, . . . , 10m, a voltage dividing board 200, and several nodes 301, 302, . . . , 30n. Each one of the node 301, 302, . . . , 30n can be a server or a mainboard.

The power supplying units 101, 102, . . . , 10m supply electrical power for the multi-node system 10. The voltage dividing board 200 converts the power into working voltages, and sends the working voltages to the nodes 301, 302, . . . , 30n. The voltage dividing board 200 is a programmable chip, for example, NXP LPC1768.

The multi-node system 10 further includes several fans 401, 402, . . . , 40n, 411, 412, . . . , 41m connected with the voltage dividing board 200. A quantity of the fans 401, 402, . . ., 40n, 411, 412, . . . , 41m is same as a quantity of the nodes 301, 302, . . . 30n and a quantity of the power supplying units 101, 102, . . . , 10m. In another embodiment, the quantity of the fans 401, 402, . . . , 40n, 411, 412, . . . , 41m may be not the same.

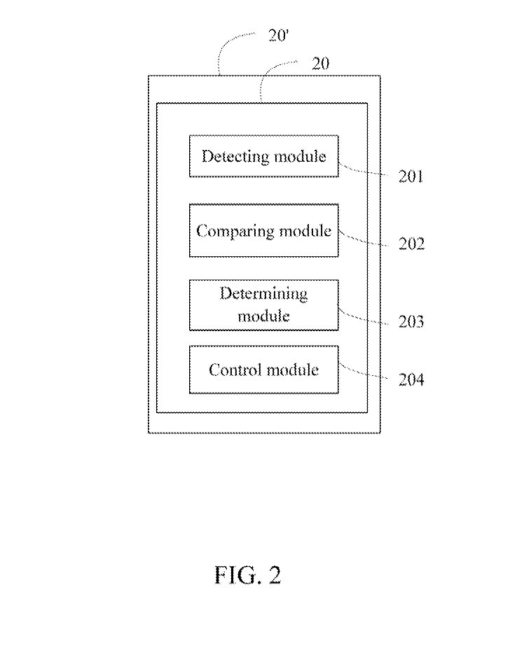

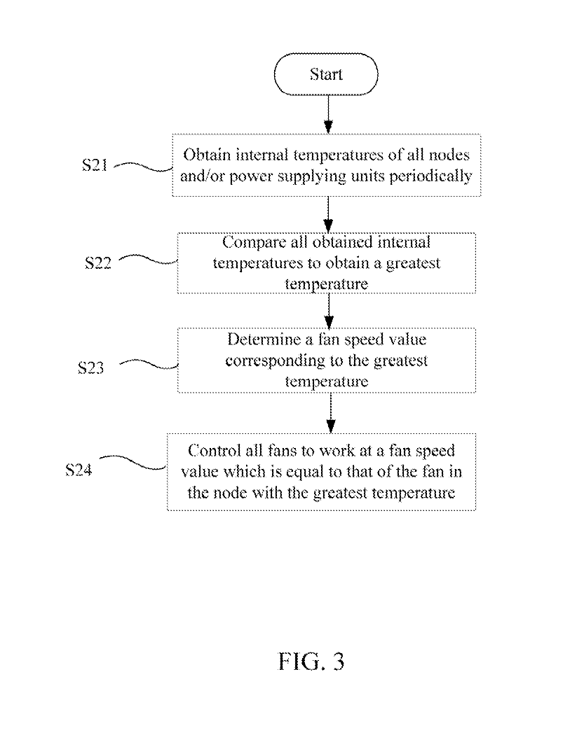

FIG. 2 is a schematic view of a fan control system used in the multi-node system in FIG. 1. The fan control system 20 runs on a processor 20′ of the voltage dividing board 200. The fan control system 20 includes a detecting module 201, a comparing module 202, a determining module 203, and a control module 204 which are program codes for instructions and executions. Functions of the modules will be described referring to FIG. 3.

FIG. 3 is a flowchart of a fan control method applied in the multi-node system of FIG. 1. The fan control method is running on the voltage dividing board 200.

In step S21, the detecting module 201 obtains internal temperatures of all nodes 301, 302, . . . , 30n and/or the power supplying units 101, 102, . . . , 10m periodically.

In step S22, the comparing module 202 compares all obtained internal temperatures to obtain the greatest temperature.

In step S23, the determining module 203 determines a fan speed value corresponding to the greatest temperature, according to a predetermined table which records relationships of temperatures associated with fan speed values.

In step S24, the control module 204 controls all fans 401, 402, . . . , 40n, 411, 412, . . . , 41m to work at the fan speed value corresponding to the greatest temperature.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A processor in a multi-node system, comprising:
a detecting module, to obtain internal temperatures of all nodes periodically;
a comparing module, to compare all obtained internal temperatures to obtain a greatest temperature;
a determining module, to determine a fan speed value corresponding to the greatest temperature according to a predetermined table which records relationships of temperatures associated with fan speed values; and
a control module, to control all fans to work at the fan speed value corresponding to the greatest temperature.

2. The processor of claim 1, wherein the detecting module further obtains internal temperatures of all power supplying units, the comparing module compares all obtained internal temperatures of the nodes and all power supplying units to obtain the greatest temperature.

3. The processor of claim 1, wherein a quantity of the fans is same as a quantity of the nodes and the power supplying units.

4. The processor of claim 3, wherein a quantity of the fans is not same as a quantity of the nodes and the power supplying units.

5. The processor of claim 1, wherein each one of the node is a server.

6. The processor of claim 1, wherein each one of the node is a mainboard.

7. The processor of claim 1, wherein the fan control system runs on a voltage dividing board which is a programmable chip.

8. A fan control method run on a processor of a voltage dividing board in a multi-node system, comprising:
obtaining internal temperatures of all nodes periodically;
comparing all obtained internal temperatures to obtain a greatest temperature;
determining a fan speed value corresponding to the greatest temperature according to a predetermined table which records relationships of temperatures associated with fan speed values; and
controlling all fans in a multi-node system to work at the fan speed value corresponding to the greatest temperature.

9. The fan control method of claim 8, wherein the method further comprises obtaining internal temperatures of all power supplying units, and comparing all obtained internal temperatures of the nodes and all power supplying units to obtain the greatest temperature.

10. The fan control method of claim 8, wherein a quantity of the fans is same as a quantity of the nodes and the power supplying units.

11. The fan control method of claim 10, wherein a quantity of the fans is not same as a quantity of the nodes and the power supplying units.

12. The fan control method of claim 8, wherein the fan control method is running on a voltage dividing board which is a programmable chip.
